(19) United States
(12) Patent Application Publication
(10) Pub. No.: US 2025/0301761 A1
(43) Pub. Date: Sep. 25, 2025

(54) SEMICONDUCTOR DEVICE

(71) Applicant: SUMITOMO ELECTRIC INDUSTRIES, LTD., Osaka (JP)

(72) Inventor: Tatsushi KANEDA, Osaka (JP)

(21) Appl. No.: 18/861,731

(22) PCT Filed: May 26, 2023
(86) PCT No.: PCT/JP2023/019756

§ 371 Date: Oct. 30, 2024

(30) Foreign Application Priority Data
Jun. 24, 2022 (JP) 2022-101718

(51) Int. Cl. H10D 80/20; H01L 23/00; H01L 23/373; H01L 25/07; H01L 25/18

(52) U.S. Cl. CPC H10D 80/251; H01L 23/3735; H01L 24/32; H01L 24/48; H01L 24/73; H01L 25/072; H01L 25/18; H10D 80/231; H01L 2224/32225; H01L 2224/48137; H01L 2224/48225; H01L 2224/73265; H01L 2924/10272; H01L 2924/12032; H01L 2924/13091

(57) ABSTRACT

A semiconductor device includes a plurality of transistors electrically connected in parallel to each other, each of the plurality of transistors including a first pad; and a conductive member. The first pad is a source pad or an emitter pad. The first pad includes a first connection region; and a second connection region and a third connection region, the first connection region being located between the second connection region and the third connection region. The semiconductor device includes a first connection member that connects the first connection region to the conductive member; a second connection member that connects second connection regions of two transistors among the plurality of transistors; and a third connection member that connects third connection regions of the two transistors among the plurality of transistors.

### TECHNICAL FIELD

The present disclosure relates to a semiconductor device.

This application is based on and claims priority to Japanese Patent Application No. 2022-101718 filed on Jun. 24, 2022, the entire contents of which are incorporated herein by reference.

### BACKGROUND

As one semiconductor device, a power module in which multiple transistors are connected in parallel to obtain a current capacity is known. Additionally, in order to suppress oscillation of the potential of a gate electrode of a transistor, a power module in which main electrodes, such as source electrodes, are connected to each other between multiple transistors is proposed (Patent Documents 1, 2, and 3).

### RELATED ART DOCUMENT

### Patent Document

[Patent Document 1] Japanese Laid-open Patent Application Publication No. 2016-184667

[Patent Document 2] Japanese Laid-open Patent Application Publication No. 2010-178615

[Patent Document 3] Japanese Laid-open Patent Application Publication No. 2013-012560

### SUMMARY OF THE INVENTION

### Problem to be Solved by the Invention

A semiconductor device according to the present disclosure includes a plurality of transistors electrically connected in parallel to each other, each of the plurality of transistors including a first pad; and a conductive member. The first pad is a source pad or an emitter pad. The first pad includes a first connection region; and a second connection region and a third connection region, the first connection region being located between the second connection region and the third connection region. The semiconductor device includes a first connection member that connects the first connection region to the conductive member; a second connection member that connects second connection regions of two transistors among the plurality of transistors; and a third connection member that connects third connection regions of the two transistors among the plurality of transistors.

### BRIEF DESCRIPTION OF THE DRAWINGS

FIG. 1 is a top view illustrating a semiconductor device according to a first embodiment.

FIG. 2 is a cross-sectional view illustrating the semiconductor device according to the first embodiment.

FIG. 3 is a schematic view illustrating a structure of a transistor.

FIG. 4 is a top view illustrating a semiconductor device according to a second embodiment.

FIG. 5 is a top view illustrating a semiconductor device according to a third embodiment.

FIG. 6 is a top view illustrating a semiconductor device according to a fourth embodiment.

FIG. 7 is a top view illustrating a semiconductor device according to a fifth embodiment.

FIG. 8 is a top view illustrating a semiconductor device according to a sixth embodiment.

FIG. 9 is a cross-sectional view illustrating the semiconductor device according to the sixth embodiment.

FIG. 10 is a view illustrating a method of using the semiconductor device according to the sixth embodiment.

### DESCRIPTION OF THE EMBODIMENTS

### Problem to be Solved by the Present Disclosure

With a conventional semiconductor device, oscillation cannot be sufficiently suppressed, and it is difficult to stabilize parallel operations among multiple transistors.

The present disclosure aims to provide a semiconductor device that can improve the stability of parallel operations among multiple transistors.

### Effects of the Present Disclosure

According to the present disclosure, the stability of parallel operations among multiple transistors can be improved.

### Description of Embodiments of the Present Disclosure

First, embodiments of the present disclosure will be listed and described.

[1] A semiconductor device according to an aspect of the present disclosure includes a plurality of transistors electrically connected in parallel to each other, each of the plurality of transistors including a first pad; and a conductive member. The first pad is a source pad or an emitter pad. The first pad includes a first connection region, and a second connection region and a third connection region, the first connection region being located between the second connection region and the third connection region. The semiconductor device includes a first connection member that connects the first connection region to the conductive member; a second connection member that connects second connection regions of two transistors among the plurality of transistors to each other; and a third connection member that connects third connection regions of the two transistors among the plurality of transistors.

In each of the plurality of transistors, the current that has reached the first connection region flows toward the first connection member, the current that has reached the second connection region flows toward the first connection member via the first connection region, and the current that has reached the third connection region flows toward the first connection member via the first connection region. That is, the current that has reached the first pad flows toward the first connection member via the first connection region located between the second connection region and the third connection region. Additionally, the second connection regions of the two transistors are connected to each other by the second connection member, and the third connection regions of the two transistors are connected to each other by the third connection member. When the second connection member of the third connection member is not provided, in the two transistors, a difference in potential between the second connection regions is likely to occur or a difference in potential between the third connection regions is likely to occur. When a difference in potential between the second connection regions or between the third connection regions occurs, oscillation may occur due to a potential difference between the first pads. With respect to the above, by providing the second connection member and the third connection member, the potential difference between the first pads can be reduced and oscillation can be suppressed. Therefore, the stability of the parallel operations among the plurality of transistors can be improved.

[2] In [1], the second connection region may include a first internal connection region and a second internal connection region separated from the first internal connection region. The semiconductor device may include a fourth connection member that connects the first internal connection region to the second internal connection region. In this case, the potential difference in the second connection regions is easily suppressed.

[3] In [2], the second connection member and the fourth connection member may be integrated with each other. In this case, the second connection member and the fourth connection member can be continuously formed by stitch bonding, and the frequency of cutting of the bonding wire is reduced, and thus damage to the transistor due to the cutting can be suppressed.

[4] In [2] or [3], the first pad may have a gap between the first internal connection region and the second internal connection region. In this case, a gate wiring can be disposed between the first internal connection region and the second internal connection region.

[5] In any one of [1] to [4], the semiconductor device may include an insulating substrate, and the plurality of transistors may be mounted on the insulating substrate. In this case, the plurality of transistors can be easily arranged close to each other.

[6] In any one of [1] to [4], the semiconductor device may include a plurality of insulating substrates, and one or more transistors among the plurality of transistors may be mounted on each of the plurality of insulating substrates. In two transistors mounted on different insulating substrates among the plurality of substrates, second connection regions may be connected to each other by the second connection member, and third connection regions may be connected to each other by the third connection member. In this case, heat transfer between the transistors mounted on the different insulating substrates is suppressed.

[7] In any one of [1] to [6], a cross-sectional area of each of the second connection member and the third connection member perpendicular to a longitudinal direction may be equal to a cross-sectional area of the first connection member perpendicular to the longitudinal direction. In this case, the first connection region, the second connection member, and the third connection member are easily formed.

[8] In any one of [1] to [6], each of the plurality of transistors may include a gate pad and a fifth connection member connected to the gate pad. A cross-sectional area of each of the second connection member and the third connection member perpendicular to a longitudinal direction may be equal to a cross-sectional area of the fifth connection member perpendicular to the longitudinal direction. In this case, the second connection member, the third connection member, and the fifth connection member are easily formed.

[9] In any one of [1] to [8], the semiconductor device may include a diode electrically connected in parallel to the plurality of transistors. In this case, the diode can be used as a freewheeling diode.

[10] In [9], the diode may be a silicon carbide diode. In this case, a high breakdown voltage can be easily achieved in the diode.

[11] In any one of [1] to [10], each of the plurality of transistors may be a silicon carbide transistor. In this case, a high breakdown voltage can be easily achieved in the transistor.

[12] In any one of [1] to [11], the first connection region, the second connection region, and the third connection region may be separated from each other when viewed from a direction perpendicular to a surface of each of the plurality of transistors on which the first pad is provided. In this case, the potential difference between the first pads is easily reduced, and oscillation is easily suppressed.

[13] A semiconductor device according to another aspect of the present disclosure includes a transistor including a first pad, a sealing material that seals the transistor, a first terminal connected to the first pad and extending from the sealing material in a first direction, and a second terminal connected to the first pad and extending from the sealing material in a second direction different from the first direction. The first pad is a source pad or an emitter pad.

In the case where a plurality of semiconductor devices are used such that the transistors are electrically connected in parallel, by connecting the second terminals to each other, the potential difference between the first pads can be reduced and oscillation can be suppressed. Therefore, the stability of the parallel operations among the plurality of transistors can be improved.

[14] In [13], the semiconductor device may include a first wire that connects the first pad to the first terminal, and a second wire that connects the first pad to the second terminal. In this case, the first pad and the first terminal can be easily connected, and the first pad and the second terminal can be easily connected.

[15] In [13] or [14], the semiconductor device may include a third terminal connected to the first pad and extending from the sealing material in a direction opposite to the second terminal. In this case, by linearly arranging the plurality of semiconductor devices and connecting the second terminal to the third terminal, the potential difference between the first pads can be reduced.

[16] In [15], the semiconductor device may include a third wire that connects the first pad to the third terminal. In this case, the first pad and the third terminal can be easily connected.

[17] In any one of to [16], the transistor may be a silicon carbide transistor. In this case, a high breakdown voltage can be easily achieved in the transistor.

### Details of Embodiments of the Present Disclosure

Hereinafter, embodiments of the present disclosure will be described in detail, but the present disclosure is not limited thereto. Here, in the present specification and the drawings, components having substantially the same functional configuration are denoted by the same reference symbols, and duplicated description thereof may be omitted. In the present specification and drawings, the X1-X2 direction, the Y1-Y2 direction, and the Z1-Z2 direction are directions orthogonal to each other. A plane including the X1-X2 direction and the Y1-Y2 direction is defined as an XY plane, a plane including the Y1-Y2 direction and the Z1-Z2 direction is defined as a YZ plane, and a plane including the Z1-Z2 direction and the X1-X2 direction is defined as a ZX plane. For convenience, the Z1 direction is the upward direction, and the Z2 direction is the downward direction. In the present disclosure, the plan view indicates that an object is viewed from the Z1 side.

### First Embodiment

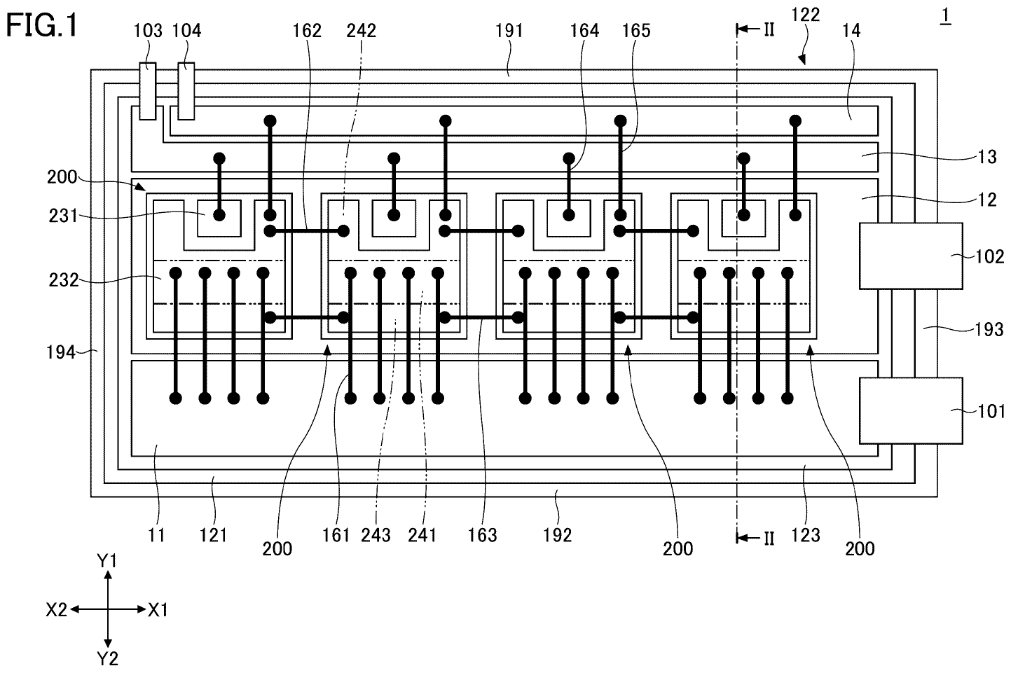

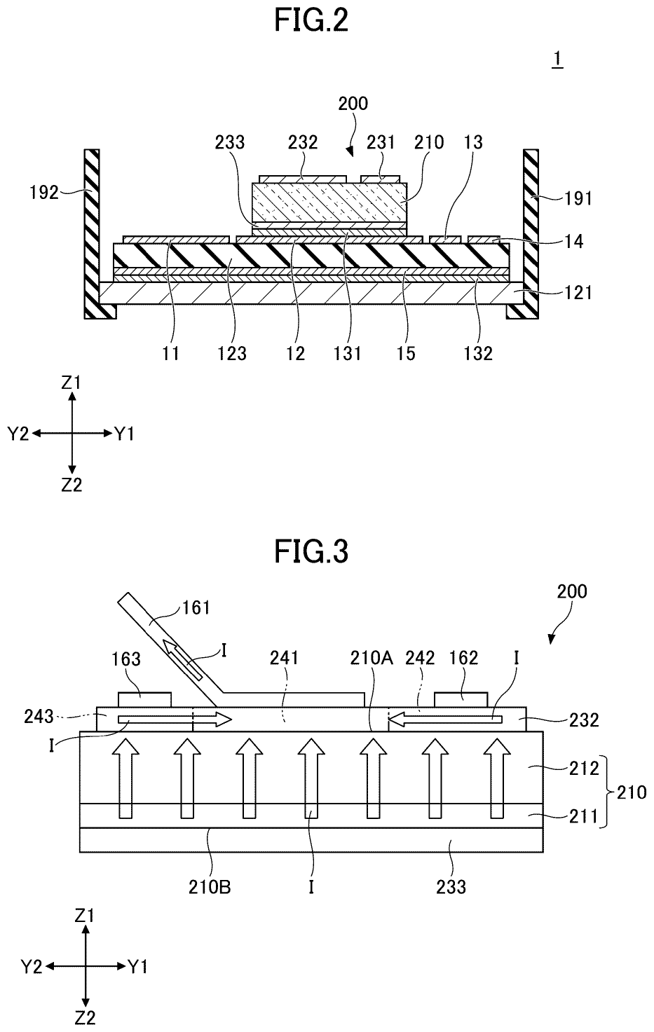

First, a first embodiment will be described. FIG. 1 is a top view illustrating a semiconductor device according to the first embodiment. FIG. 2 is a cross-sectional view illustrating the semiconductor device according to the first embodiment. FIG. 2 corresponds to the cross-sectional view taken along the line II-II in FIG. 1.

As illustrated in FIG. 1 and FIG. 2, a semiconductor device 1 according to the first embodiment includes a heat dissipation plate 121, a housing 122, a source terminal 101, a drain terminal 102, a gate terminal 103, and a sense source terminal 104. The semiconductor device 1 further includes a first conductive layer 11, a second conductive layer 12, a third conductive layer 13, a fourth conductive layer 14, and an insulating substrate 123. The semiconductor device 1 further includes multiple transistors 200. The number of the transistors 200 is not limited and is four, for example.

The transistor 200 is a field effect transistor, and includes a silicon carbide substrate 210, a gate pad 231, a source pad 232, and a drain electrode 233. The gate pad 231 and the source pad 232 are provided on the upper surface (the Z1 side surface) of the transistor 200, and the drain electrode 233 is provided on the lower surface (the Z2 side surface) of the transistor 200. The source pad 232 includes a first connection region 241, a second connection region 242, and a third connection region 243. The first connection region 241 is located on the Y2 side of the second connection region 242, and the third connection region 243 is located on the Y2 side of the first connection region 241. Thus, the first connection region 241 is located between the second connection region 242 and the third connection region 243. The source pad 232 is an example of a first pad.

The heat dissipation plate 121 is, for example, a plate body having a rectangular shape in plan view and a uniform thickness. A material of the heat dissipation plate 121 is a metal having a high thermal conductivity, for example, copper (Cu), a copper alloy, or aluminum (Al). The heat dissipation plate 121 is fixed to a cooler or the like by using a thermal interface material (TIM) or the like.

The housing 122 is formed in a frame shape in plan view, for example, and the outer shape of the housing 122 is substantially the same as the outer shape of the heat dissipation plate 121. A material of the housing 122 is an insulator, such as a resin. The housing 122 includes a pair of side walls 191 and 192 facing each other, and a pair of end walls 193 and 194 connecting both ends of the side walls 191 and 192. The side walls 191 and 192 are disposed parallel to the ZX plane, and the end walls 193 and 194 are disposed parallel to the YZ plane. The side wall 191 is disposed on the Y1 side of the side wall 192, and the end wall 193 is disposed on the X1 side of the end wall 194.

The gate terminal 103 and the sense source terminal 104 are disposed on the upper surface (the Z1 side surface) of the side wall 191. The gate terminal 103 and the sense source terminal 104 are each formed of a metal plate.

The source terminal 101 and the drain terminal 102 are disposed on the upper surface (the Z1 side surface) of the end wall 193. For example, the drain terminal 102 is disposed on the Y1 side of the source terminal 101. The source terminal 101 and the drain terminal 102 are each formed of a metal plate.

Inside the housing 122, the insulating substrate 123 is disposed on the Z1 side of the heat dissipation plate 121. The first conductive layer 11, the second conductive layer 12, the third conductive layer 13, and the fourth conductive layer 14 are provided on the Z1 side surface of the insulating substrate 123. A fifth conductive layer 15 is provided on the Z2 side surface of the insulating substrate 123. The fifth conductive layer 15 is bonded to the heat dissipation plate 121 by a second bonding material 132. A material of the insulating substrate 123 is, for example, silicon nitride (SiN), aluminum oxide (Al₂O₃), or aluminum nitride (AlN). A material of the first conductive layer 11, the second conductive layer 12, the third conductive layer 13, the fourth conductive layer 14, and the fifth conductive layer 15 is, for example, copper. A material of the second bonding material 132 is, for example, solder, such as lead-free solder containing tin (Sn). The first conductive layer 11 is an example of a conductive member.

The source terminal 101 is connected to the first conductive layer 11, and the drain terminal 102 is connected to the second conductive layer 12. The gate terminal 103 is connected to the third conductive layer 13, and the sense source terminal 104 is connected to the fourth conductive layer 14.

The semiconductor device 1 further includes a first bonding wire 161, a second bonding wire 162, a third bonding wire 163, a fourth bonding wire 164, and a fifth bonding wire 165.

The transistors 200 are provided on the second conductive layer 12. The transistors 200 are arranged along the X1-X2 direction. The first connection region 241 of the source pad 232 of the transistor 200 is connected to the first conductive layer 11 by multiple first bonding wires 161. The drain electrode 233 of the transistor 200 is bonded to the second conductive layer 12 by a first bonding material 131. A material of the first bonding material 131 is, for example, solder, such as lead-free solder containing tin (Sn). The gate pad 231 of the transistor 200 is connected to the third conductive layer 13 by the fourth bonding wire 164. The source pad 232 of the transistor 200 is also connected to the fourth conductive layer 14 by the fifth bonding wire 165. Between the transistors 200 adjacent to each other in the X1-X2 direction, the second connection regions 242 are connected to each other by the second bonding wire 162, and the third connection regions 243 are connected to each other by the third bonding wire 163. The first bonding wire 161 is an example of a first connection member, the second bonding wire 162 is an example of a second connection member, and the third bonding wire 163 is an example of a third connection member. The fourth bonding wire 164 is an example of a fifth connection member.

Here, a current path in the transistor 200 will be described. FIG. 3 is a schematic view illustrating a structure of the transistor 200.

As illustrated in FIG. 3, the transistor 200 mainly includes the silicon carbide substrate 210, the gate pad 231, the source pad 232, and the drain electrode 233.

The silicon carbide substrate 210 includes a silicon carbide single-crystal substrate 211 and a silicon carbide epitaxial layer 212 on the silicon carbide single-crystal substrate 211. The silicon carbide substrate 210 has a main surface 210A and a main surface 210B opposite to the main surface 210A. The silicon carbide epitaxial layer 212 forms the main surface 210A, and the silicon carbide single-crystal substrate 211 forms the main surface 210B. Although not illustrated, multiple transistor cells are provided in the silicon carbide epitaxial layer 212. The gate pad 231 and the source pad 232 are provided on the main surface 210A, and the drain electrode 233 is provided on the main surface 210B.

In each transistor cell, a current I flows from the drain electrode 233 toward the source pad 232. Additionally, in the source pad 232, the current I flows toward the first connection region 241 to which the first bonding wire 161 is connected. Then, the current I flows to the first bonding wire 161 via the first connection region 241. The current I that has reached the first connection region 241 flows through the first bonding wire 161 as it is. Additionally, the current I that has reached the second connection region 242 flows to the first bonding wire 161 via the first connection region 241, and the current I that has reached the third connection region 243 flows to the first bonding wire 161 via the first connection region 241. The length and the electrical resistance are different between a current path between the transistor cell close to the first connection region 241 and the first bonding wire 161 and a current path between the transistor cell far from the first connection region 241 and the first bonding wire 161. Therefore, in the case where the second bonding wire 162 or the third bonding wire 163 is not provided, in the two transistors 200, a difference in potential between the second connection regions 242 is likely to occur or a difference in potential between the third connection regions 243 is likely to occur. When a difference in potential occurs between the second connection regions 242 or between the third connection regions 243, a potential difference between the source pads 232 occurs and oscillation may occur due to the potential difference. With respect to the above, in the present embodiment, the second bonding wire 162 and the third bonding wire 163 are provided, and thus a potential difference between the source pads 232 can be reduced, and oscillation can be suppressed. Therefore, the stability of the parallel operations among multiple transistors 200 can be improved.

Additionally, multiple transistors 200 are mounted on the insulating substrate 123, and thus the multiple transistors 200 can be easily arranged close to each other.

The transistor 200 is a silicon carbide transistor including the silicon carbide substrate 210, and thus a high breakdown voltage is easily achieved.

The cross-sectional area of each of the second bonding wire 162 and the third bonding wire 163 perpendicular to the longitudinal direction is not limited, but may be equal to the cross-sectional area of the first bonding wire 161 perpendicular to the longitudinal direction. In this case, the first bonding wire 161, the second bonding wire 162, and the third bonding wire 163 can be formed without replacing wires. Therefore, the first bonding wire 161, the second bonding wire 162, and the third bonding wire 163 are easily formed.

Additionally, the cross-sectional area of each of the second bonding wire 162 and the third bonding wire 163 perpendicular to the longitudinal direction may be equal to the cross-sectional area of the fourth bonding wire 164 perpendicular to the longitudinal direction. In this case, the fourth bonding wire 164, the second bonding wire 162, and the third bonding wire 163 can be formed without replacing wires. Therefore, the fourth bonding wire 164, the second bonding wire 162, and the third bonding wire 163 are easily formed.

### Second Embodiment

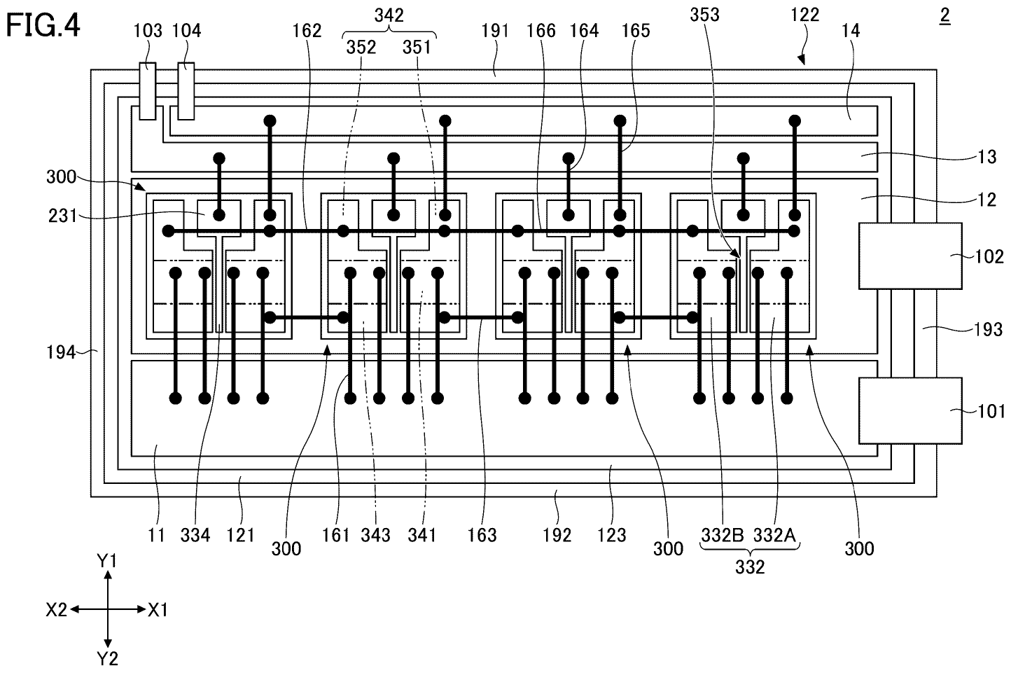

Next, a second embodiment will be described. The second embodiment is different from the first embodiment mainly in the configuration of the transistor and in that a bonding wire is further included. FIG. 4 is a top view illustrating the semiconductor device according to the second embodiment.

As illustrated in FIG. 4, a semiconductor device 2 according to the second embodiment includes a transistor 300 instead of the transistor 200. The transistor 300 includes the gate pad 231, a source pad 332, the drain electrode 233, and a gate wiring (gate runner) 234. The gate pad 231, the gate wiring 334, and the source pad 332 are provided on the upper surface (the Z1 side surface) of the semiconductor device 1, and the drain electrode 233 is provided on the lower surface (the Z2 side surface) of the semiconductor device 1.

The source pad 332 includes a first connection region 341, a second connection region 342, and a third connection region 343. The first connection region 341 is located on the Y2 side of the second connection region 342, and the third connection region 343 is located on the Y2 side of the first connection region 341. Thus, the first connection region 341 is located between the second connection region 342 and the third connection region 343.

The source pad 332 includes a source pad 332A and a source pad 332B. The source pads 332A and 332B are separated from each other in the X1-X2 direction. The source pad 332A is located on the X1 side of the source pad 332B. The first connection region 341, the second connection region 342, and the third connection region 343 extend over the source pads 332A and 332B. The second connection region 342 includes a first internal connection region 351 in the source pad 332A and a second internal connection region 352 in the source pad 332B. The second internal connection region 352 is separated from the first internal connection region 351. The source pad 332 has a gap 353 between the first internal connection region 351 and the second internal connection region 352. The first internal connection region 351 is located on the X1 side of the second internal connection region 352. The source pad 332 is an example of the first pad.

The gate wiring 334 is provided between the source pad 332A and the source pad 332B and extends along the Y1-Y2 direction. The gate wiring 334 is connected to the gate pad 231. The gate wiring 334 is provided in the gap 353.

The other configurations of the transistor 300 are the same as those of the transistor 200.

The semiconductor device 2 further includes a sixth bonding wire 166. Inside the transistor 200, the first internal connection region 351 and the second internal connection region 352 are connected by the sixth bonding wire 166. The sixth bonding wire 166 is an example of a fourth connection member.

The other configurations of the second embodiment are the same as those of the first embodiment.

The second embodiment also provides the same effect as the first embodiment. Additionally, the first internal connection region 351 and the second internal connection region 352 are connected by the sixth bonding wire 166, and thus the potential difference in the second connection regions 342 is easily suppressed. Further, the gap 353 is present between the first internal connection region 351 and the second internal connection region 352, and thus the gate wiring 334 can be disposed between the first internal connection region 351 and the second internal connection region 352.

The second bonding wire 162 and the sixth bonding wire 166 may be integrated. For example, the second bonding wire 162 and the sixth bonding wire 166 may be formed by stitch bonding. In this case, the frequency of cutting the bonding wires is reduced when the second bonding wire 162 and the sixth bonding wire 166 are formed, and damage to the transistor 300 due to the cutting can be suppressed.

### Third Embodiment

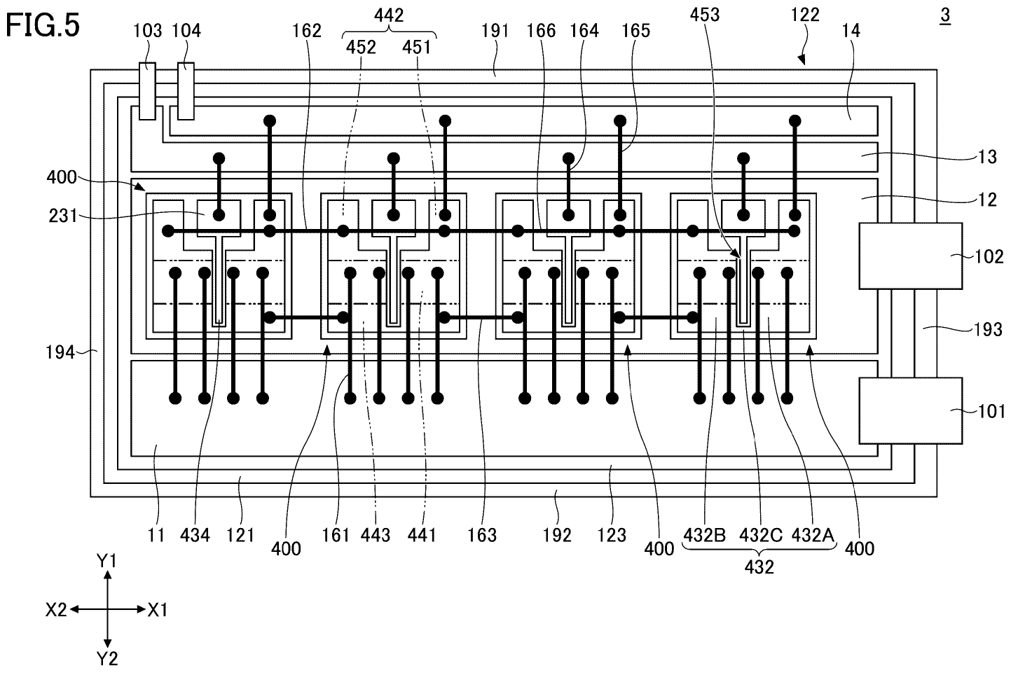

Next, a third embodiment will be described. The third embodiment is different from the second embodiment mainly in the configuration of the transistor. FIG. 5 is a top view illustrating a semiconductor device according to the third embodiment.

As illustrated in FIG. 5, a semiconductor device 3 according to the third embodiment includes a transistor 400 instead of the transistor 300. The transistor 400 includes the gate pad 231, a source pad 432, the drain electrode 233, and a gate wiring (gate runner) 434. The gate pad 231, the gate wiring 434, and the source pad 432 are provided on the upper surface (the Z1 side surface) of the semiconductor device 1, and the drain electrode 233 is provided on the lower surface (the Z2 side surface) of the semiconductor device 1.

The source pad 432 includes a first connection region 441, a second connection region 442, and a third connection region 443. The first connection region 441 is located on the Y2 side of the second connection region 442, and the third connection region 443 is located on the Y2 side of the first connection region 441. Thus, the first connection region 441 is located between the second connection region 442 and the third connection region 443.

The source pad 432 includes a source pad 432A, a source pad 432B, and a conductive region 432C. The source pads 432A and 432B are separated from each other in the X1-X2 direction. The source pad 432A is located on the X1 side of the source pad 432B. The first connection region 441, the second connection region 442, and the third connection region 443 extend over the source pads 332A and 332B. The conductive region 432C is connected to a corner of the source pad 432A on the X2 side and the Y2 side and a corner of the source pad 432B on the X1 side and the Y2 side, and electrically connects the source pads 432A and 432B to each other. The conductive region 432C is included in the third connection region 443. The second connection region 442 includes a first internal connection region 451 in the source pad 432A and a second internal connection region 452 in the source pad 432B. The second internal connection region 452 is separated from the first internal connection region 451. The source pad 432 has a gap 453 between the first internal connection region 451 and the second internal connection region 452. The first internal connection region 451 is located on the X1 side of the second internal connection region 452. The source pad 432 is an example of the first pad.

The gate wiring 434 is provided between the source pad 432A and the source pad 432B and extends along the Y1-Y2 direction. The gate wiring 434 is connected to the gate pad 231. The end of the gate wiring 434 on the Y2 side is located in the vicinity of the conductive region 432C, but is separated from the conductive region 432C. The gate wiring 434 is provided in the gap 453.

The other configurations of the transistor 400 are the same as those of the transistor 300. Additionally, the other configurations of the third embodiment are the same as those of the second embodiment.

The third embodiment also provides the same effects as the first embodiment. Additionally, the first internal connection region 451 and the second internal connection region 452 are connected by the sixth bonding wire 166, and thus the potential difference in the second connection regions 442 is easily suppressed. Further, the gap 453 is present between the first internal connection region 451 and the second internal connection region 452, and thus the gate wiring 434 can be disposed between the first internal connection region 451 and the second internal connection region 452.

### Fourth Embodiment

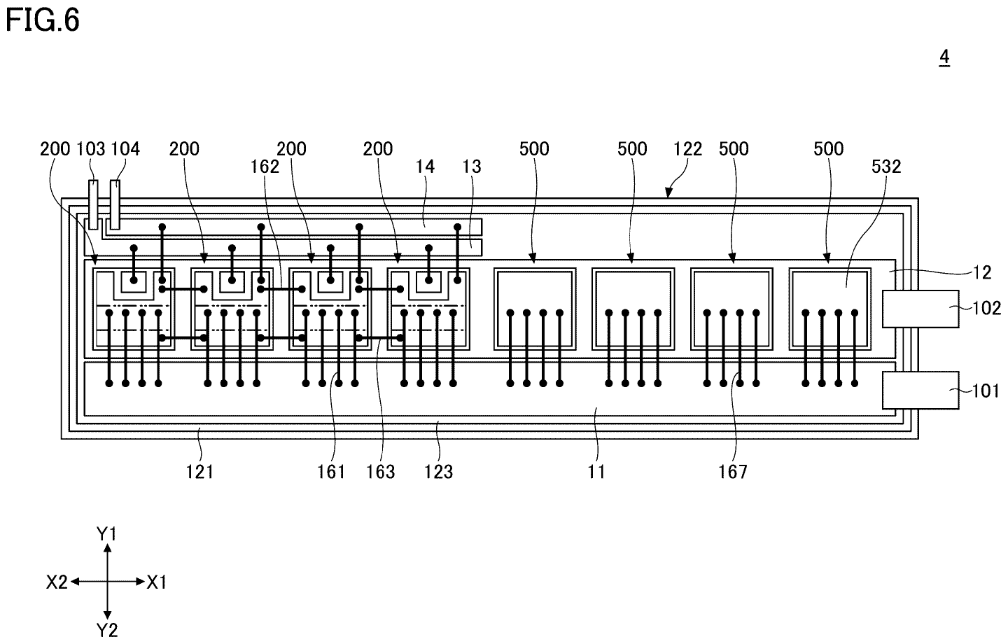

Next, a fourth embodiment will be described. The fourth embodiment differs from the first embodiment mainly in that a diode is included. FIG. 6 is a top view illustrating a semiconductor device according to the fourth embodiment.

As illustrated in FIG. 6, a semiconductor device 4 according to the fourth embodiment includes multiple diodes 500 in addition to multiple transistors 200. The number of the diodes 500 is not limited, and is four, for example. The semiconductor device 4 further includes a seventh bonding wire 167.

The diode 500 is a Schottky barrier diode, and includes an anode pad 532 and a cathode electrode (not illustrated). The anode pad 532 is provided on the upper surface (the Z1 side surface) of the diode 500, and the cathode electrode is provided on the lower surface (the Z2 side surface) of the diode 500.

The diodes 500 are provided on the second conductive layer 12. The diodes 500 are arranged along the X1-X2 direction. The diodes 500 are located on the X1 side of the transistors 200. The anode pad 532 of the diode 500 is connected to the first conductive layer 11 by the multiple seventh bonding wires 167. The cathode electrode of the diode 500 is bonded to the second conductive layer 12 by a third bonding material (not illustrated). A material of the third bonding material is, for example, solder, such as lead-free solder containing tin (Sn).

The other configurations of the fourth embodiment are the same as those of the first embodiment.

The fourth embodiment also provides the same effect as the first embodiment. Additionally, the diode 500 can be used as a freewheeling diode. When the diode 500 is a silicon carbide diode including a silicon carbide substrate, a high breakdown voltage is easily achieved.

### Fifth Embodiment

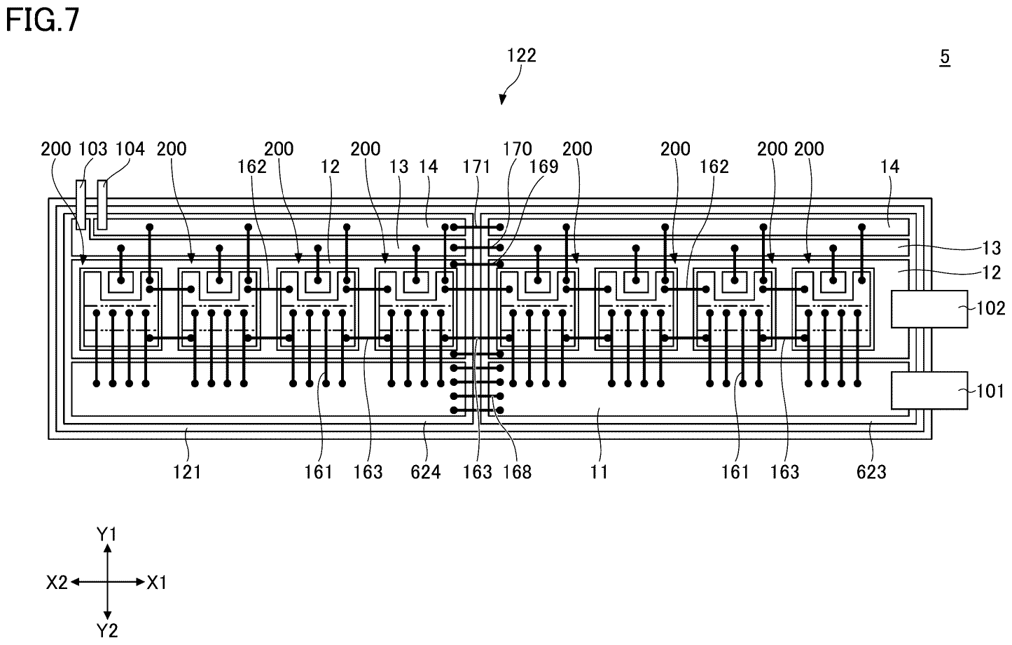

Next, a fifth embodiment will be described. The fifth embodiment is different from the first embodiment mainly in the configuration of the insulating substrate. FIG. 7 is a top view illustrating a semiconductor device according to the fifth embodiment.

As illustrated in FIG. 7, a semiconductor device 5 according to the fifth embodiment includes insulating substrates 623 and 624 instead of the insulating substrate 123.

Inside the housing 122, the insulating substrates 623 and 624 are disposed on the Z1 side of the heat dissipation plate 121. The insulating substrate 623 is located on the X1 side of the insulating substrate 624. The first conductive layer 11, the second conductive layer 12, the third conductive layer 13, and the fourth conductive layer 14 are provided on the Z1 side surface of the insulating substrate 623 and the Z1 side surface of the insulating substrate 624. The fifth conductive layer 15 is provided on the Z2 side surface of the insulating substrate 623 and on the Z2 side surface of the insulating substrate 624. A material of the insulating substrates 623 and 624 is, for example, silicon nitride (SiN), aluminum oxide (Al₂O₃), or aluminum nitride (AlN).

Four transistors 200 are provided on the second conductive layer 12 on the insulating substrate 623, and another four transistors 200 are provided on the second conductive layer 12 on the insulating substrate 624. The transistors 200 are arranged along the X1-X2 direction.

The semiconductor device 5 further includes an eighth bonding wire 168, a ninth bonding wire 169, a tenth bonding wire 170, and an eleventh bonding wire 171. The first conductive layer 11 on the insulating substrate 623 and the first conductive layer 11 on the insulating substrate 624 are connected by the multiple eighth bonding wires 168. The second conductive layer 12 on the insulating substrate 623 and the second conductive layer 12 on the insulating substrate 624 are connected by the multiple ninth bonding wires 169. The third conductive layer 13 on the insulating substrate 623 and the third conductive layer 13 on the insulating substrate 624 are connected by the tenth bonding wire 170. The fourth conductive layer 14 on the insulating substrate 623 and the fourth conductive layer 14 on the insulating substrate 624 are connected by the eleventh bonding wire 171.

The source terminal 101 is connected to the first conductive layer 11 on the insulating substrate 623, and the drain terminal 102 is connected to the second conductive layer 12 on the insulating substrate 623. The gate terminal 103 is connected to the third conductive layer 13 on the insulating substrate 624, and the sense source terminal 104 is connected to the fourth conductive layer 14 on the insulating substrate 624.

The other configurations of the fifth embodiment are the same as those of the first embodiment.

The fifth embodiment also provides the same effects as the first embodiment. Additionally, heat transfer between the transistor 200 mounted on the insulating substrate 623 and the transistor 200 mounted on the insulating substrate 624 is suppressed.

In the present disclosure, the second connection member and the third connection member are not limited to bonding wires, and may be copper clips, ribbons, or the like.

### Sixth Embodiment

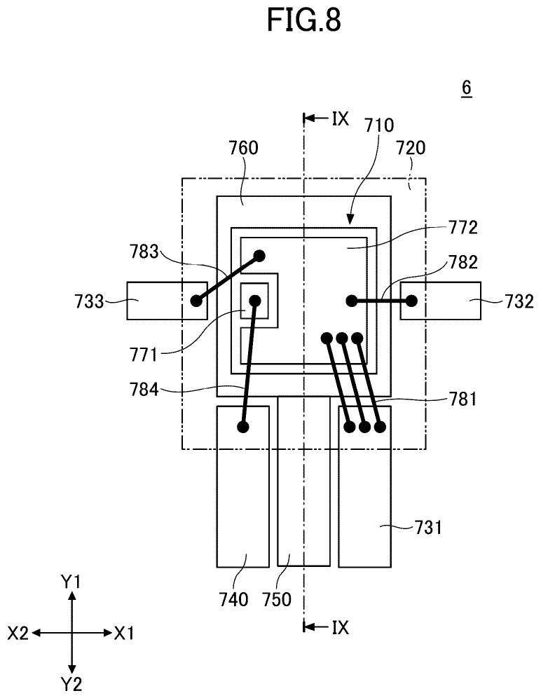

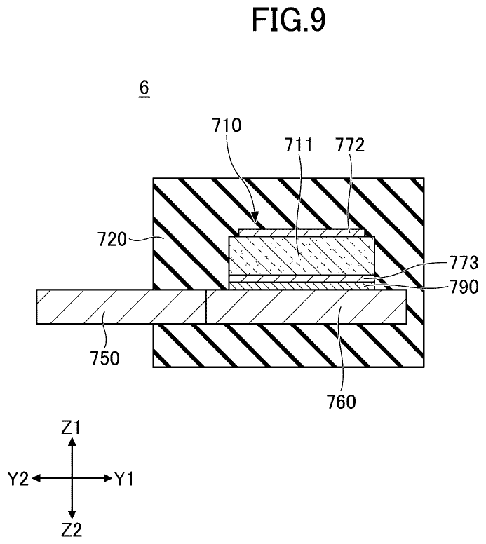

Next, a sixth embodiment will be described. FIG. 8 is a top view illustrating a semiconductor device according to the sixth embodiment. FIG. 9 is a cross-sectional view illustrating the semiconductor device according to the sixth embodiment. FIG. 9 corresponds to a cross-sectional view taken along the line IX-IX in FIG. 8.

As illustrated in FIG. 8 and FIG. 9, a semiconductor device 6 according to the sixth embodiment includes a transistor 710, a sealing material 720, a first source terminal 731, a second source terminal 732, a third source terminal 733, a gate terminal 740, a drain terminal 750, and a die pad 760. In FIG. 8, the sealing material 720 is seen through.

The semiconductor device 6 further includes a first bonding wire 781, a second bonding wire 782, a third bonding wire 783, and a fourth bonding wire 784. The first bonding wire 781, the second bonding wire 782, the third bonding wire 783, and the fourth bonding wire 784 are, for example, aluminum (Al) wires.

The transistor 710 is a field effect transistor, and includes a silicon carbide substrate 711, a gate pad 771, a source pad 772, and a drain electrode 773. The gate pad 771 and the source pad 772 are provided on the upper surface (the Z1 side surface) of the transistor 710, and the drain electrode 773 is provided on the lower surface (the Z2 side surface) of the transistor 710. The source pad 772 is an example of the first pad.

The drain terminal 750 is formed integrally with the die pad 760 and extends from the die pad 760 toward the Y2 side. The first source terminal 731 is located on the X1 side of the drain terminal 750 and extends parallel to the drain terminal 750. The gate terminal 740 is located on the X2 side of the drain terminal 750 and extends parallel to the drain terminal 750. The second source terminal 732 is located on the X1 side of the die pad 760, separated from the die pad 760, and extends along the X1-X2 direction. The third source terminal 733 is located on the X2 side of the die pad 760, separated from the die pad 760, and extends along the X1-X2 direction.

The transistor 710 is provided on the die pad 760. The drain electrode 773 of the transistor 710 is bonded to the die pad 760 by a bonding material 790. A material of the bonding material 790 is, for example, solder, such as lead-free solder containing tin (Sn). The source pad 772 of the transistor 710 is connected to the first source terminal 731 by the multiple first bonding wires 781. The source pad 772 of the transistor 710 is also connected to the second source terminal 732 by the second bonding wire 782. The source pad 772 of the transistor 710 is also connected to the third source terminal 733 by the third bonding wire 783. The gate pad 771 of the transistor 710 is connected to the gate terminal 740 by the fourth bonding wire 784. The first source terminal 731 is an example of a first terminal, the second source terminal 732 is an example of a second terminal, and the third source terminal 733 is an example of a third terminal. Additionally, the first bonding wire 781 is an example of a first wire, the second bonding wire 782 is an example of a second wire, and the third bonding wire 783 is an example of a third wire.

The sealing material 720 seals the transistor 710. The sealing material 720 also seals the first bonding wire 781, the second bonding wire 782, the third bonding wire 783, and the fourth bonding wire 784. The sealing material 720 also seals the connection of the first source terminal 731 with the first bonding wire 781, the connection of the second source terminal 732 with the second bonding wire 782, and the connection of the third source terminal 733 with the third bonding wire 783. The sealing material 720 also seals the connection of the gate terminal 740 with the fourth bonding wire 784.

The first source terminal 731, the gate terminal 740, and the drain terminal 750 extend from the sealing material 720 toward the Y2 side. The second source terminal 732 extends from the sealing material 720 toward the X1 side. The third source terminal 733 extends from the sealing material 720 toward the X2 side. The direction in which the first source terminal 731, the gate terminal 740, and the drain terminal 750 extend is an example of a first direction. The direction in which the second source terminal 732 extends is an example of a second direction.

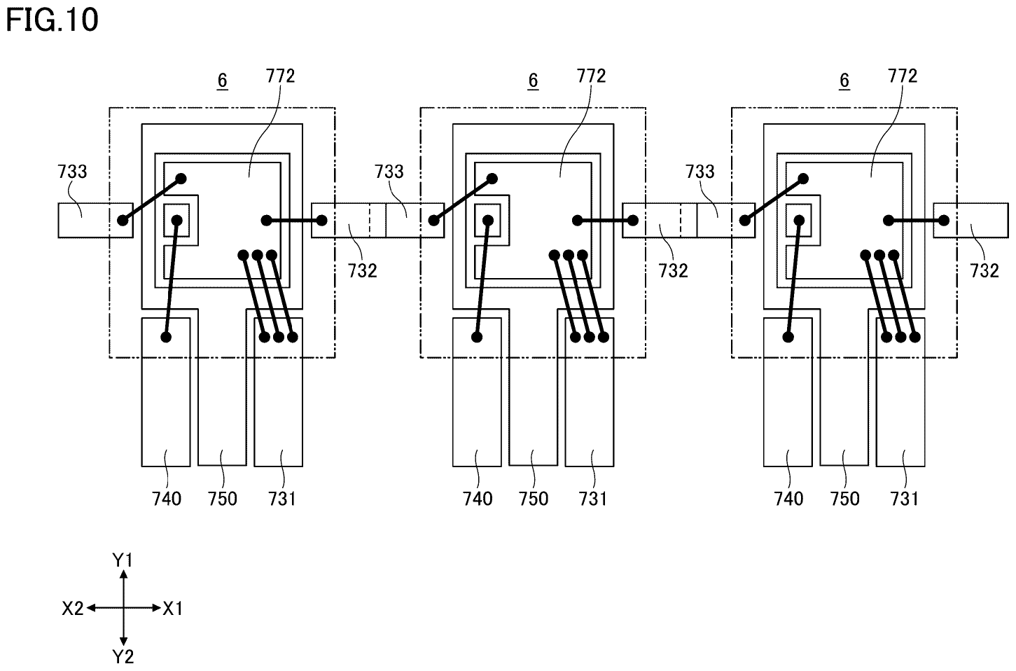

Here, a method of using the semiconductor device 6 according to the sixth embodiment will be described. FIG. 10 is a view illustrating a method of using the semiconductor device 6 according to the sixth embodiment.

As illustrated in FIG. 10, multiple semiconductor devices 6 are used. The multiple semiconductor devices 6 are connected in parallel to each other. Additionally, the second source terminal 732 and the third source terminal 733 are connected between two semiconductor devices 6 among the multiple semiconductor devices 6. For example, the second source terminal 732 and the third source terminal 733 are connected to each other by welding, soldering, or screwing.

As described above, even when the discrete semiconductor device 6 is used, the variation in the potential of the source pad 772 between the semiconductor devices 6 can be suppressed and oscillation can be suppressed. Therefore, the stability of the parallel operations among the multiple transistors 710 can be improved.

Additionally, by using the first bonding wire 781, the second bonding wire 782, and the third bonding wire 783, the source pad 772 can be easily connected to the first source terminal 731, the second source terminal 732, and the third source terminal 733.

The transistor 710 is a silicon carbide transistor including the silicon carbide substrate 711, and thus a high breakdown voltage is easily achieved.

Here, the transistors 200, 300, 400, and 710 are not necessarily field-effect transistors, and may be, for example, insulated gate bipolar transistors (IGBTs). In this case, an emitter pad is used as the first pad. The IGBT may be a silicon carbide IGBT.

Although the embodiments have been described in detail above, the present invention is not limited to the specific embodiments, and various modifications and changes can be made within the scope described in the claims.

### DESCRIPTION OF REFERENCE SYMBOLS

1, 2, 3, 4, 5, 6: semiconductor device
11: first conductive layer (conductive member)
12: second conductive layer
13: third conductive layer
14: fourth conductive layer
15: fifth conductive layer
101: source terminal
102: drain terminal
103: gate terminal
104: sense source terminal
121: heat dissipation plate
122: housing
123, 623, 624: insulating substrate
131: first bonding material
132: second bonding material
161: first bonding wire (first connection member)
162: second bonding wire (second connection member)
163: third bonding wire (third connection member)
164: fourth bonding wire (fifth connection member)
165: fifth bonding wire
166: sixth bonding wire (fourth connection member)
167: seventh bonding wire
168: eighth bonding wire
169: ninth bonding wire
170: tenth bonding wire
171: eleventh bonding wire
191, 192: side wall
193, 194: end wall
200, 300, 400: transistor
210: silicon carbide substrate
210A: main surface
210B: main surface
211: silicon carbide single-crystal substrate
212: silicon carbide epitaxial layer
231: gate pad
232, 332, 332A, 332B, 432, 432A, 432B: source pad (first pad)
233: drain electrode
234, 334, 434: gate wiring
241 341 441: first connection region
242 342 442: second connection region
243 343 443: third connection region
351, 451: first internal connection region
352, 452: second internal connection region
353, 453: gap
432C: conductive region
500: diode
532: anode pad
710: transistor
711: silicon carbide substrate
720: sealing material
731: first source terminal
732: second source terminal
733: third source terminal
740: gate terminal
750: drain terminal
760: die pad
771: gate pad
772: source pad (first pad)
773: drain electrode
781: first bonding wire (first wire)
782: second bonding wire (second wire)
783: third bonding wire (third wire)
784: fourth bonding wire
790: bonding material
I: current

1. A semiconductor device comprising:
a plurality of transistors electrically connected in parallel to each other, each of the plurality of transistors including a first pad; and
a conductive member,
wherein the first pad is a source pad or an emitter pad,
wherein the first pad includes:
a first connection region; and
a second connection region and a third connection region, the first connection region being located between the second connection region and the third connection region: and
wherein the semiconductor device comprises:
a first connection member that connects the first connection region to the conductive member;
a second connection member that connects second connection regions of two transistors among the plurality of transistors to each other; and
a third connection member that connects third connection regions of the two transistors among the plurality of transistors.

2. The semiconductor device as claimed in claim 1,
wherein the second connection region includes:
a first internal connection region; and
a second internal connection region separated from the first internal connection region, and
wherein the semiconductor device comprises a fourth connection member that connects the first internal connection region to the second internal connection region.

3. The semiconductor device as claimed in claim 2, wherein the second connection member and the fourth connection member are integrated.

4. The semiconductor device as claimed in claim 2, wherein the first pad has a gap between the first internal connection region and the second internal connection region.

5. The semiconductor device as claimed in claim 1, comprising an insulating substrate,
wherein the plurality of transistors are mounted on the insulating substrate.

6. The semiconductor device as claimed in claim 1, comprising a plurality of insulating substrates,
wherein one or more transistors among the plurality of transistors are mounted on each of the plurality of insulating substrates, and
wherein in two transistors mounted on different insulating substrates among the plurality of insulating substrates, second connection regions are connected to each other by the second connection member and third connection regions are connected to each other by the third connection member.

7. The semiconductor device as claimed in claim 1, wherein a cross-sectional area of each of the second connection member and the third connection member perpendicular to a longitudinal direction is equal to a cross-sectional area of the first connection member perpendicular to the longitudinal direction.

8. The semiconductor device as claimed in claim 1,
wherein each of the plurality of transistors includes a gate pad,
wherein the semiconductor device comprises a fifth connection member connected to the gate pad, and
wherein a cross-sectional area of each of the second connection member and the third connection member perpendicular to a longitudinal direction is equal to a cross-sectional area of the fifth connection member perpendicular to the longitudinal direction.

9. The semiconductor device as claimed in claim 1, comprising a diode electrically connected in parallel to the plurality of transistors.

10. The semiconductor device as claimed in claim 9, wherein the diode is a silicon carbide diode.

11. The semiconductor device as claimed in claim 1, wherein each of the plurality of transistors is a silicon carbide transistor.

12. The semiconductor device as claimed in claim 1, wherein the first connection region, the second connection region, and the third connection region are separated from each other when viewed in a direction perpendicular to a surface of each of the plurality of transistors on which the first pad is provided.

13. A semiconductor device comprising:
a transistor including a first pad;
a sealing material that seals the transistor;
a first terminal connected to the first pad and extending from the sealing material in a first direction; and
a second terminal connected to the first pad and extending from the sealing material in a second direction different from the first direction,
wherein the first pad is a source pad or an emitter pad.

14. The semiconductor device as claimed in claim 13, comprising:
a first wire that connects the first pad to the first terminal; and
a second wire that connects the first pad to the second terminal.

15. The semiconductor device as claimed in claim 13, comprising a third terminal connected to the first pad and extending from the sealing material in a direction opposite to the second terminal.

16. The semiconductor device as claimed in claim 15, comprising a third wire that connects the first pad to the third terminal.

17. The semiconductor device as claimed in claim 13, wherein the transistor is a silicon carbide transistor.

18. A semiconductor device comprising:
a first transistor and a second transistor connected in parallel to each other, each of the first transistor and the second transistor including a first pad;
a conductive member,
a first connection member that connects a first connection region of the first pad of the first transistor to the conductive member;
another first connection member that connects a first connection region of the first pad of the second transistor to the conductive member;
a second connection member that connects a second connection region of the first pad of the first transistor to a second connection region of the first pad of the second transistor; and
a third connection member that connects a third connection region of the first pad of the first transistor to a third connection region of the first pad of the second transistor,
wherein the first pad is a source pad or an emitter pad,
wherein the first connection region of the first pad of the first transistor is located between the second connection region of the first pad of the first transistor and the third connection region of the first pad of the first transistor, and
wherein the first connection region of the first pad of the second transistor is located between the second connection region of the first pad of the second transistor and the third connection region of the first pad of the second transistor.
